(19) United States
(12) Patent Application Publication
(10) Pub. No.: US 2025/0149526 A1
(43) Pub. Date: May 8, 2025

(54) SEMICONDUCTOR PACKAGE INCLUDING A PLURALITY OF STACKED CHIPS

(71) Applicant: SAMSUNG ELECTRONICS CO., LTD, SUWON-SI (KR)

(72) Inventors: Wonjung JANG, Suwon-si (KR); Dongjoo CHOI, Suwon-si (KR)

(21) Appl. No.: 18/825,162

(22) Filed: Sep. 5, 2024

(30) Foreign Application Priority Data
Nov. 6, 2023 (KR) 10-2023-0151907
Dec. 4, 2023 (KR) 10-2023-0173562

(51) Int. Cl. H01L 25/18; H01L 23/00; H01L 23/31; H10B 80/00

(52) U.S. Cl. CPC H01L 25/18; H01L 23/3171; H01L 23/3185; H01L 24/05; H01L 24/16; H01L 24/32; H01L 24/73; H10B 80/00; H01L 2224/05155; H01L 2224/05582; H01L 2224/05644; H01L 2224/05647; H01L 2224/05666; H01L 2224/16148; H01L 2224/32135; H01L 2224/73204; H01L 2225/06513; H01L 2225/06541; H01L 2924/1431

(57) ABSTRACT

A semiconductor package includes: a buffer die; memory dies on the buffer die; a bonding layer between the memory dies; and a molding member disposed on the buffer die and the memory dies, wherein each of the memory dies includes: a first substrate having first and second surfaces; a first conductive pad and a first conductive connection member stacked on the first substrate; and a second conductive pad disposed on the first substrate, wherein the second conductive pad of a first memory die of the memory dies contacts the first conductive connection member of a second memory die of the memory dies. The first memory die is disposed under the second memory die. The first conductive pad includes a first conductive pattern and a second conductive pattern. The second conductive pad includes a third conductive pattern and a fourth conductive pattern. The fourth conductive pattern contacts the third conductive pattern.

### CROSS-REFERENCE TO RELATED APPLICATION

This application claims priority under 35 U.S.C. § 119 to Korean Patent Application Nos. 10-2023-0151907, filed on Nov. 6, 2023, and 10-2023-0173562, filed on Dec. 4, 2023, in the Korean Intellectual Property Office (KIPO), the disclosures of which are incorporated by reference herein in their entireties.

### TECHNICAL FIELD

Example embodiments of the present inventive concept relate to a semiconductor package. More particularly, example embodiments of the present inventive concept relate to a semiconductor package including a plurality of stacked chips.

### DISCUSSION OF THE RELATED ART

Typically, a high bandwidth memory (HBM) package may include a plurality of memory chips stacked on a logic chip in a vertical direction, and the memory chips may be bonded with each other by a bonding layer. If the bonding state between the memory chips is strong, the HBM package may have increased performance.

### SUMMARY

According to example embodiments of the present inventive concept, a semiconductor package includes: a buffer die; memory dies sequentially stacked on the buffer die; a bonding layer disposed between neighboring ones of the memory dies, wherein the bonding layer bonds the neighboring ones of the memory dies with each other; and a molding member disposed on the buffer die, wherein the molding member covers sidewalls of the memory dies, wherein: each of the memory dies includes: a first substrate having first and second surfaces that are opposite to each other in a vertical direction substantially perpendicular to an upper surface of the buffer die; a first conductive pad and a first conductive connection member that are stacked on the first surface of the first substrate; and a second conductive pad disposed on the second surface of the first substrate, wherein the second conductive pad of a first memory die of the memory dies contacts the first conductive connection member of a second memory die of the memory dies, wherein the first memory die is disposed under the second memory die, wherein the first conductive pad includes a first conductive pattern and a second conductive pattern sequentially stacked downwardly in the vertical direction, wherein the second conductive pad includes a third conductive pattern and a fourth conductive pattern sequentially stacked upwardly in the vertical direction, wherein the fourth conductive pattern contacts the third conductive pattern, and wherein each of the first and third conductive patterns includes nickel, wherein the second conductive pattern includes copper, and the fourth conductive pattern includes gold.

According to example embodiments of the present inventive concept, a semiconductor package includes: a buffer die; memory dies stacked on the buffer die; a bonding layer disposed between neighboring ones of the memory dies, wherein the bonding layer bonds the neighboring ones of the memory dies with each other; and a molding member disposed on the buffer die, wherein the molding member covers sidewalls of the memory dies. Each of the memory dies includes: a substrate having first and second surfaces that are opposite to each other in a vertical direction substantially perpendicular to an upper surface of the buffer die; a through electrode structure extending through the substrate, wherein a portion of the through electrode structure protrudes beyond the second surface of the substrate; and a protective pattern structure including: a first protective pattern; and a second protective pattern disposed on the first protective pattern. Each of the memory dies further includes: a first conductive pad and a conductive connection member that are stacked on the first surface of the first substrate; and a second conductive pad disposed on the protective pattern structure, wherein the second conductive pad contacts the through electrode structure, wherein the second conductive pad of a first memory die of the memory dies contacts the conductive connection member of a second memory die of the memory dies, wherein the first memory die is disposed under the second memory die, wherein the bonding layer has a thickness of about 6.0 um to about 7.0 um, and wherein the first protective pattern has a thickness of about 0.5 um to about 1.3 um.

According to example embodiments of the present inventive concept, a semiconductor package includes: a buffer die; first memory dies stacked on the buffer die; a second memory die disposed on an uppermost first memory die of the first memory dies; a bonding layer disposed between the first memory dies and between the uppermost first memory die and second memory die, wherein the bonding layer bonds the uppermost first memory die and second memory die with each other; and a molding member disposed on the buffer die, wherein the molding member covers sidewalls of the first memory die and the second memory die. Each of the first memory dies includes: a first substrate having first and second surfaces that are opposite to each other in a vertical direction substantially perpendicular to an upper surface of the buffer die; a first through electrode structure extending through the first substrate, wherein a portion of the first through electrode structure protrudes beyond the second surface of the first substrate; and a first protective pattern structure disposed on the second surface of the first substrate. The first protective pattern structure covers the portion of the first through electrode structure and includes: a first protective pattern; and a second protective pattern disposed on the first protective pattern. Each of the first memory dies further includes: a first conductive pad and a first conductive connection member that are stacked beneath the first surface of the first substrate in the vertical direction; and a second conductive pad disposed on the first protective pattern structure, wherein the second conductive pad contacts the first through electrode structure. The second conductive pad of a first first memory die of the first memory dies contacts the first conductive connection member of a second first memory die of the memory dies, wherein the first first memory die is disposed under the second first memory. The first conductive pad includes a first conductive pattern and a second conductive pattern stacked downwardly in the vertical direction. The second conductive pad includes a third conductive pattern and a fourth conductive pattern stacked upwardly in the vertical direction. The fourth conductive pattern contacts the third conductive pattern. Each of the first and third conductive patterns includes nickel. The second conductive pattern includes copper, and the fourth conductive pattern includes gold.

### BRIEF DESCRIPTION OF THE DRAWINGS

FIG. 1 is a cross-sectional view illustrating a semiconductor package according to example embodiments of the present inventive concept.

FIG. 2 is an enlarged cross-sectional view of region X of FIG. 1.

FIG. 3 is an enlarged cross-sectional view of region Y of FIG. 1.

FIGS. 4, 5, 6, 7, 8, 9, 10, 11, 12, 13, 14, 15 and 16 are cross-sectional views illustrating a method of manufacturing a semiconductor package according to example embodiments of the present inventive concept.

FIG. 17 is a cross-sectional view illustrating an electronic device according to example embodiments of the present inventive concept.

### DETAILED DESCRIPTION OF EXAMPLE EMBODIMENTS

Hereinafter, example embodiments will be explained in detail with reference to the accompanying drawings. Hereinafter, a direction substantially parallel to an upper surface of a wafer or a substrate may be referred to as a horizontal direction, and a direction substantially perpendicular to the upper surface of the wafer or the substrate may be referred to as a vertical direction.

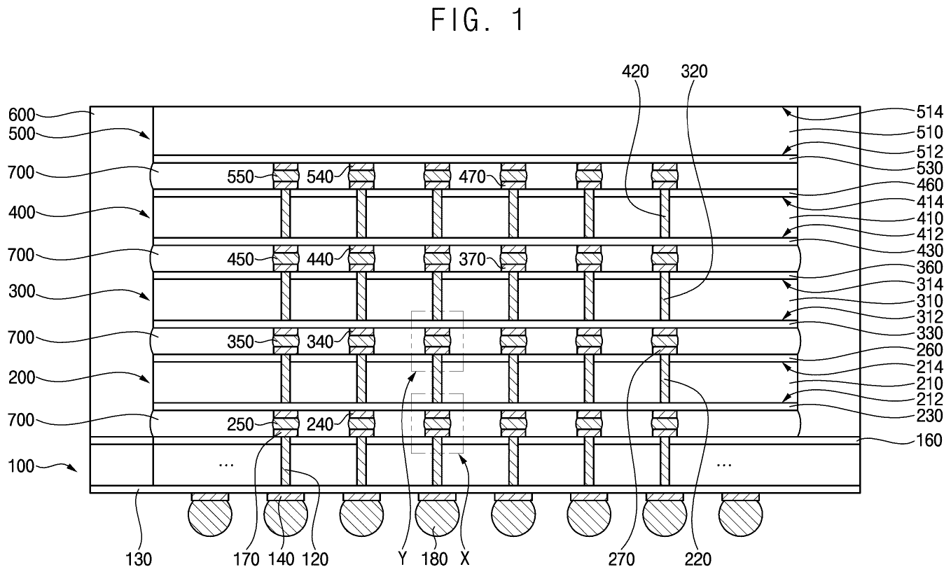

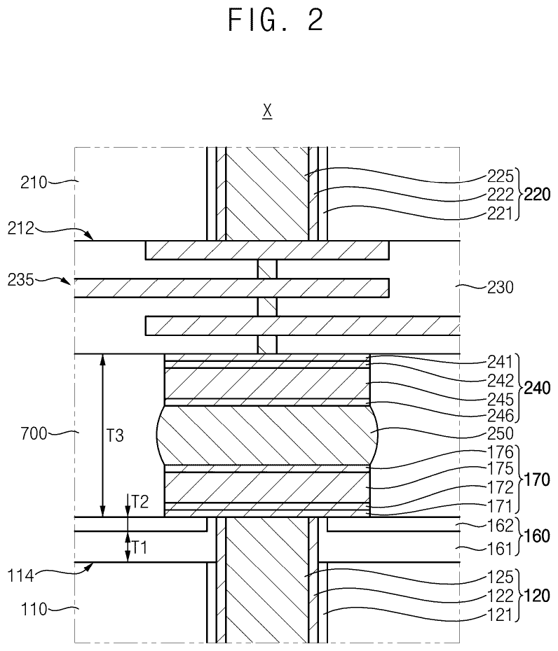

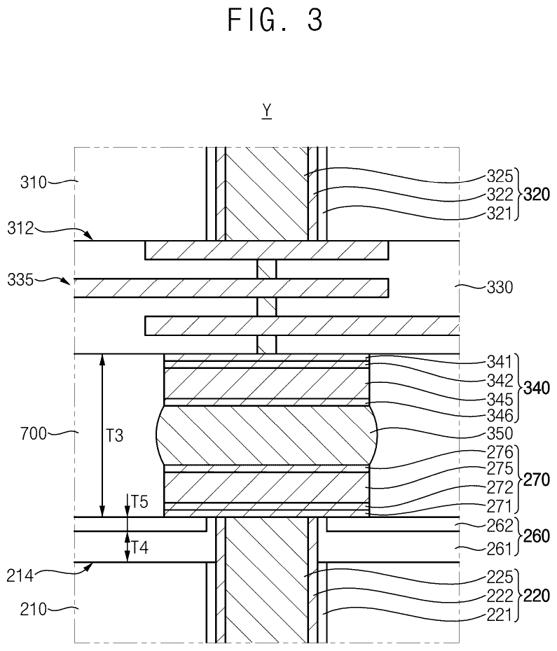

FIG. 1 is a cross-sectional view illustrating a semiconductor package according to example embodiments of the present inventive concept, and FIG. 2 is an enlarged cross-sectional view of region X of FIG. 1. FIG. 3 is an enlarged cross-sectional view of region Y of FIG. 1.

Referring to FIGS. 1 to 3, the semiconductor package may include a first semiconductor chip 100, second to fifth semiconductor chips 200, 300, 400 and 500 sequentially stacked on the first semiconductor chip 100, a bonding layer 700 disposed between the first to fifth semiconductor chips 100, 200, 300, 400 and 500, and a molding member 600 disposed on the first semiconductor chip 100 and covering sidewalls of the second to fifth semiconductor chips 200, 300, 400 and 500.

FIGS. 1 to 3 show that the semiconductor package includes fourth semiconductor chips 200, 300, 400 and 500 stacked on the first semiconductor chip 100; however, the present inventive concept is not necessarily limited thereto, and the semiconductor package may include more than four semiconductor chips, e.g., eight or sixteenth semiconductor chips. In example embodiments of the present inventive concept, the semiconductor package may be a high bandwidth memory (HBM) package.

In example embodiments of the present inventive concept, the first semiconductor chip 100 may be a buffer die, and may include a logic device, e.g., a controller. Each of the second to fifth semiconductor chips 200, 300, 400 and 500 may be a core die, and may include a volatile memory device, e.g., DRAM device, SRAM device, etc., or a non-volatile memory device, e.g., flash memory device, EEPROM device, etc.

The first semiconductor chip 100 may include a first substrate 110 having first and second surfaces 112 and 114 that are opposite to each other in the vertical direction, a first through electrode structure 120 extending through the first substrate 110, a first insulating interlayer and a second insulating interlayer 130 sequentially stacked in the vertical direction beneath the first surface 112 of the first substrate 110, a first conductive pad 140 disposed beneath the second insulating interlayer 130, a first protective pattern structure 160 disposed on the second surface 114 of the first substrate 110, and a second conductive pad 170 disposed on the first protective pattern structure 160 and on upper surface of the first through electrode structure 120. For example, the second conductive pad 170 contacts an upper surface of the first through electrode structure 120.

The first substrate 110 may include a semiconductor material, e.g., silicon, germanium, silicon-germanium, or a III-V group compound semiconductor, e.g., GaP, GaAs, GaSb, etc. In example embodiments of the present inventive concept, the first substrate 110 may be a silicon-on-insulator (SOI) substrate or a germanium-on-insulator (GOI) substrate.

A circuit device, e.g., a logic device may be formed beneath the first surface 112 of the first substrate 110. The circuit device may include circuit patterns, which may be covered by the first insulating interlayer.

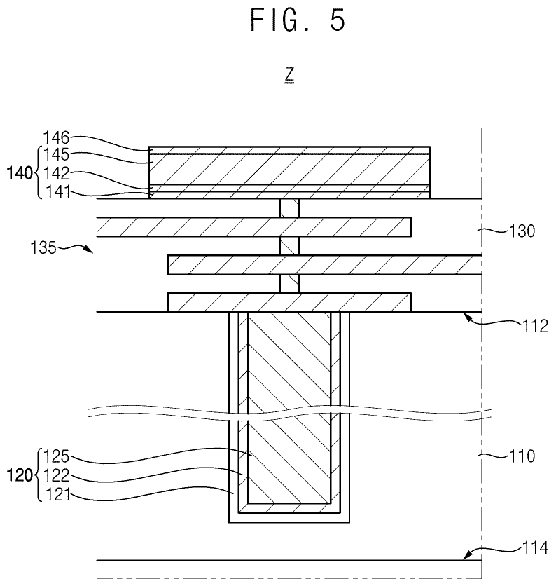

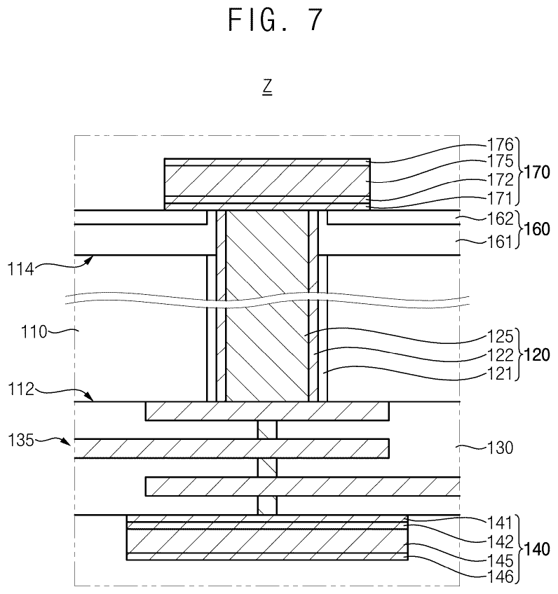

A first wiring structure 135 (see, e.g., FIGS. 5 and 7) may be disposed in the second insulating interlayer 130. The first wiring structure 135 may include, e.g., wirings, vias, contact plugs, etc.

The first insulating interlayer and the second insulating interlayer 130 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The first conductive pad 140 may be disposed under the second insulating interlayer 130, and may contact the first wiring structure 135 to be electrically connected thereto. In example embodiments of the present inventive concept, a plurality of first conductive pads 140 may be spaced apart from each other in the horizontal direction.

In example embodiments of the present inventive concept, the first conductive pad 140 may include first and second seed patterns 141 and 142 and first and second conductive patterns 145 and 146 sequentially stacked downwardly in the vertical direction from the second insulating interlayer 130 (refer to FIG. 7). Each of the first and second seed patterns 141 and 142 may include, e.g., titanium and/or copper, and each of the first and second conductive patterns 145 and 146 may include, e.g., nickel and/or copper.

The first through electrode structure 120 may extend through the first substrate 110 in the vertical direction. A portion of the first through electrode structure 120 may protrude upwardly in the vertical direction, and may be covered by the first protective pattern structure 160. For example, the first through electrode 120 may penetrate the first protective pattern structure 160. A plurality of first through electrode structures 120 may be spaced apart from each other in the horizontal direction. In example embodiments of the present inventive concept, the first through electrode structure 120 may include a first through electrode 125 extending in the vertical direction, a first barrier pattern 122 covering a sidewall of the first through electrode 125, and a first insulation pattern 121 covering an outer sidewall of the first barrier pattern 122. However, in an example embodiment of the present inventive concept, the first insulation pattern 121 might not cover an upper portion of the outer sidewall of the first barrier pattern 122. For example, the first insulation pattern 121 might not extend beyond the second surface 114 of the first substrate 110.

The first through electrode 125 may include a metal, e.g., copper, aluminum, etc. The first barrier pattern 122 may include a metal nitride, e.g., titanium nitride, tantalum nitride, etc., and the first insulation pattern 121 may include an oxide, e.g., silicon oxide or an insulating nitride, e.g., silicon nitride.

In an example embodiment of the present inventive concept, the first through electrode structure 120 may extend through the first protective pattern structure 160, the first substrate 110 and the first insulating interlayer to contact the first wiring structure 135, and may be electrically connected to the first conductive pad 140 by the first wiring structure 135.

In addition, the first through electrode structure 120 may extend through the first protective pattern structure 160, the first substrate 110 and the first insulating interlayer and the second insulating interlayer 130 to contact the first conductive pad 140, and may be electrically connected to the first conductive pad 140. In addition, the first through electrode structure 120 may extend through the first protective pattern structure 160 and the first substrate 110 to contact one of the circuit patterns included in the circuit device covered by the first insulating interlayer, and may be electrically connected to the first conductive pad 140 by the one of the first circuit patterns and the first wiring structure 135.

The first protective pattern structure 160 may be formed on the second surface 114 of the first substrate 110, and may surround an upper portion of the first through electrode structure 120. In example embodiments of the present inventive concept, the first protective pattern structure 160 may contact an outer sidewall of an upper portion of the first barrier pattern 122 of the first through electrode structure 120.

In example embodiments of the present inventive concept, the first protective pattern structure 160 may include a first protective pattern 161 and a second protective pattern 162 sequentially stacked in the vertical direction on the second surface 114 of the first substrate 110. A portion of the first protective pattern 161 adjacent to the first through electrode structure 120 may protrude upwardly in the vertical direction, and an upper surface of the portion of the first protective pattern 161 may be substantially coplanar with an upper surface of the first through electrode structure 120. The portion of the first protective pattern 161 may be disposed between the second protective pattern 162 and the first barrier pattern 122. An outer sidewall of the portion of the first protective pattern 161 may be covered by the second protective pattern 162.

The first protective pattern 161 may include an oxide, e.g., silicon oxide, and the second protective pattern 162 may include an insulating nitride, e.g., silicon nitride.

The first protective pattern 161 may have a first thickness T1 in the vertical direction, except for the portion of the first protective pattern 161 that is adjacent to the first through electrode structure 120, and the second protective pattern 162 may have a second thickness T2 in the vertical direction. In example embodiments of the present inventive concept, the first thickness T1 may be in a range of about 0.5 um to about 1.3 um, and the second thickness T2 may be about 0.35 um.

The second conductive pad 170 may be electrically connected to the first conductive pad 140 by the first through electrode structure 120 and the first wiring structure 135. In example embodiments of the present inventive concept, a plurality of second conductive pads 170 may be spaced apart from each other in the horizontal direction.

In example embodiments of the present inventive concept, the second conductive pad 170 may include third and fourth seed patterns 171 and 172 and third and fourth conductive patterns 175 and 176 sequentially stacked upwardly in the vertical direction from the first protective pattern structure 160. In example embodiments of the present inventive concept, the fourth conductive pattern 176 may contact the third conductive pattern 175, and the third and fourth conductive patterns 175 and 176 may have substantially the same planar area. For example, the fourth conductive pattern 176 may contact an entirety of an upper surface of the third conductive pattern 175. Each of the third and fourth seed patterns 171 and 172 may include, e.g., titanium and/or copper, and each of the third and fourth conductive patterns 175 and 176 may include, e.g., nickel and/or gold.

The second semiconductor chip 200 may include a second substrate 210 having first and second surfaces 212 and 214 that are opposite to each other in the vertical direction, a second through electrode structure 220 extending through the second substrate 210, a third insulating interlayer and a fourth insulating interlayer 230 sequentially stacked in the vertical direction beneath the first surface 212 of the second substrate 210, a third conductive pad 240 disposed beneath the fourth insulating interlayer 230, a second protective pattern structure 260 disposed on the second surface 214 of the second substrate 210, and a fourth conductive pad 270 disposed on the second protective pattern structure 260 and contacting an upper surface of the second through electrode structure 220.

The second substrate 210 may include a semiconductor material, e.g., silicon, germanium, silicon-germanium, or a III-V group compound semiconductor, e.g., GaP, GaAs, GaSb, etc. In example embodiments of the present inventive concept, the second substrate 210 may be a silicon-on-insulator (SOI) substrate or a germanium-on-insulator (GOI) substrate.

A circuit device, e.g., a volatile memory device such as DRAM device, SRAM device, etc., or a non-volatile memory device such as flash memory device, EEPROM device, etc., may be formed beneath the first surface 212 of the second substrate 210. The circuit device may include circuit patterns, which may be covered by the third insulating interlayer.

A second wiring structure 235 may be disposed in the fourth insulating interlayer 230. The second wiring structure 235 may include, e.g., wirings, vias, contact plugs, etc.

The third insulating interlayer and the fourth insulating interlayer 230 may include, e.g., silicon oxide or a low-k dielectric material, e.g., an oxide doped with carbon or fluorine. The wirings, the vias, the contact plugs, etc., may include a conductive material, e.g., a metal, a metal nitride, a metal silicide, etc.

The third conductive pad 240 may be disposed under the fourth insulating interlayer 230, and may contact the second wiring structure 235 to be electrically connected thereto. In example embodiments of the present inventive concept, a plurality of third conductive pads 240 may be spaced apart from each other in the horizontal direction.

In example embodiments of the present inventive concept, the third conductive pad 240 may include fifth and sixth seed patterns 241 and 242 and fifth and sixth conductive patterns 245 and 246 sequentially stacked downwardly in the vertical direction from the fourth insulating interlayer 230. Each of the fifth and sixth seed patterns 241 and 242 may include, e.g., titanium and/or copper, and each of the fifth and sixth conductive patterns 245 and 246 may include, e.g., nickel and/or copper.

The second through electrode structure 220 may extend through the second substrate 210 in the vertical direction. A portion of the second through electrode structure 220 may protrude upwardly in the vertical direction, and may be covered by the second protective pattern structure 260. A plurality of second through electrode structures 220 may be spaced apart from each other in the horizontal direction. In example embodiments of the present inventive concept, the second through electrode structure 220 may include a second through electrode 225 extending in the vertical direction, a second barrier pattern 222 covering a sidewall of the second through electrode 225, and a second insulation pattern 221 covering an outer sidewall of the second barrier pattern 222. However, in an example embodiment of the present inventive concept, the second insulation pattern 221 might not cover an upper portion of the outer sidewall of the second barrier pattern 222. For example, the second insulation pattern 221 might not extend beyond the second surface 214 of the second substrate 210.

The second through electrode 225 may include a metal, e.g., copper, aluminum, etc. The second barrier pattern 222 may include a metal nitride, e.g., titanium nitride, tantalum nitride, etc., and the second insulation pattern 221 may include an oxide, e.g., silicon oxide or an insulating nitride, e.g., silicon nitride.

In an example embodiment of the present inventive concept, the second through electrode structure 220 may extend through the second protective pattern structure 260, the second substrate 210 and the third insulating interlayer, and may contact the second wiring structure 235. The second through electrode structure 220 may be electrically connected to the third conductive pad 240 by the second wiring structure 235.

In addition, the second through electrode structure 220 may extend through the second protective pattern structure 260, the second substrate 210 and the third insulating interlayer and the fourth insulating interlayer 230, and may contact the third conductive pad 240. The second through electrode structure 220 may be electrically connected to the third conductive pad 240. In addition, the second through electrode structure 220 may extend through the second protective pattern structure 260 and the second substrate 210 to contact one of the circuit patterns included in the circuit device covered by the third insulating interlayer, and may be electrically connected to the third conductive pad 240 by the one of the circuit patterns and the second wiring structure 235.

The second protective pattern structure 260 may be formed on the second surface 214 of the second substrate 210, and may at least partially surround an upper portion of the second through electrode structure 220. In an example embodiment of the present inventive concept, the second protective pattern structure 260 may contact an outer sidewall of an upper portion of the second barrier pattern 222 of the second through electrode structure 220.

In example embodiments of the present inventive concept, the second protective pattern structure 260 may include a third protective pattern 261 and a fourth protective pattern 262 sequentially stacked in the vertical direction on the second surface 214 of the second substrate 210. A portion of the third protective pattern 261 that is adjacent to the second through electrode structure 220 may protrude upwardly in the vertical direction, and an upper surface of the portion of the second protective pattern 261 may be substantially coplanar with an upper surface of the second through electrode structure 220. An outer sidewall of the portion of the third protective pattern 261 may be covered by the fourth protective pattern 262. For example, the portion of the third protective pattern 261 may be disposed between the second barrier pattern 222 and the fourth protective pattern 262.

The third protective pattern 261 may include an oxide, e.g., silicon oxide, and the fourth protective pattern 262 may include an insulating nitride, e.g., silicon nitride.

The third protective pattern 261 may have a fourth thickness T4 in the vertical direction, except for the portion of the third protective pattern 261 adjacent to the second through electrode structure 220, and the fourth protective pattern 262 may have a fifth thickness T5 in the vertical direction. In example embodiments of the present inventive concept, the fourth and fifth thicknesses T4 and T5 may be substantially the same as the first and second thicknesses T1 and T2, respectively. Thus, the fourth thickness T4 may be in a range of about 0.5 um to about 1.3 um, and the fifth thickness T5 may be about 0.35 um.

The fourth conductive pad 270 may be electrically connected to the third conductive pad 240 by the second through electrode structure 220 and the second wiring structure 235. In example embodiments of the present inventive concept, a plurality of fourth conductive pads 270 may be spaced apart from each other in the horizontal direction.

In example embodiments of the present inventive concept, the fourth conductive pad 270 may include seventh and eighth seed patterns 271 and 272 and seventh and eighth conductive patterns 275 and 276 sequentially stacked upwardly in the vertical direction from the second protective pattern structure 260. In example embodiments of the present inventive concept, the eighth conductive pattern 276 may contact the seventh conductive pattern 275, and the seventh and eighth conductive patterns 275 and 276 may have substantially the same planar area. For example, the eighth conductive pattern 276 may contact an entirety of an upper surface of the seventh conductive pattern 275. Each of the seventh and eighth seed patterns 271 and 272 may include, e.g., titanium and/or copper, and each of the seventh and eighth conductive patterns 275 and 276 may include, e.g., nickel and/or gold.

The first conductive connection member 250 may be disposed between and contact the second and third conductive pads 170 and 240. The first conductive connection member 250 may be, e.g., a conductive bump. The first conductive connection member 250 may include a metal, e.g., tin, or an alloy of tin/silver, tin/copper, tin/indium, tin/silver/copper, etc.

The bonding layer 700 be disposed between the first and second semiconductor chips 100 and 200, and may bind the first and second semiconductor chips 100 and 200 with each other. The bonding layer 700 may at least partially surround the second and third conductive pads 170 and 240. The bonding layer 700 may include a non-conductive film (NCF), e.g., thermosetting resin.

The third to fifth semiconductor chips 300, 400 and 500 may be sequentially stacked in the vertical direction on the second semiconductor chip 200, and the bonding layer 700 may be disposed therebetween. For example, the bonding layer 700 may be disposed between the second to fifth semiconductor chips 200, 300, 400, and 500.

Each of the third to fifth semiconductor chips 300, 400 and 500 may have a structure substantially the same as or similar to that of the second semiconductor chip 200, and thus, repeated explanations and descriptions are omitted herein.

The third semiconductor chip 300 may include a third substrate 310 having first and second surfaces 312 and 314 that are opposite to each other in the vertical direction, a third through electrode structure 320 extending through the third substrate 310, a fifth insulating interlayer and a sixth insulating interlayer 330 sequentially stacked in the vertical direction beneath the first surface 312 of the third substrate 310, a fifth conductive pad 340 disposed beneath the sixth insulating interlayer 330, a third protective pattern structure 360 disposed on the second surface 314 of the third substrate 310, and a sixth conductive pad 370 disposed on the third protective pattern structure 360 and contacting an upper surface of the third through electrode structure 320.

A circuit device, e.g., a memory device may be formed beneath the first surface 312 of the third substrate 310. The circuit device may include circuit patterns, which may be covered by the fifth insulating interlayer. A third wiring structure 335 may be disposed in the sixth insulating interlayer 330.

The fifth conductive pad 340 may be disposed under the sixth insulating interlayer 330, and may contact the third wiring structure 335 to be electrically connected to the third wiring structure 335. In example embodiments of the present inventive concept, a plurality of fifth conductive pads 340 may be spaced apart from each other in the horizontal direction.

In example embodiments of the present inventive concept, the fifth conductive pad 340 may include ninth and tenth seed patterns 341 and 342 and ninth and tenth conductive patterns 345 and 346 sequentially stacked downwardly in the vertical direction from the sixth insulating interlayer 330. Each of the ninth and tenth seed patterns 341 and 342 may include, e.g., titanium and/or copper, and each of the ninth and tenth conductive patterns 345 and 346 may include, e.g., nickel and/or copper.

The third through electrode structure 320 may extend through the third substrate 310 in the vertical direction. A portion of the third through electrode structure 320 may protrude upwardly in the vertical direction, and may be covered by the third protective pattern structure 360. A plurality of third through electrode structures 320 may be spaced apart from each other in the horizontal direction. In example embodiments of the present inventive concept, the third through electrode structure 320 may include a third through electrode 325 extending in the vertical direction, a third barrier pattern 322 covering a sidewall of the third through electrode 325, and a third insulation pattern 321 covering an outer sidewall of the third barrier pattern 322. However, in an example embodiment of the present inventive concept, the third insulation pattern 321 might not cover an upper portion of the outer sidewall of the third barrier pattern 322. For example, the third insulation pattern 321 might not extend beyond the second surface 314 of the third substrate 310.

In an example embodiment of the present inventive concept, the third through electrode structure 320 may extend through the third protective pattern structure 360, the third substrate 310 and the fifth insulating interlayer, and may contact the third wiring structure 335. The third through electrode structure 320 may be electrically connected to the fifth conductive pad 340 by the third wiring structure 335.

The third protective pattern structure 360 may be formed on the second surface 314 of the third substrate 310, and may at least partially surround an upper portion of the third through electrode structure 320. In an example embodiment of the present inventive concept, the third protective pattern structure 360 may contact an outer sidewall of an upper portion of the third barrier pattern 322 of the third through electrode structure 320.

In example embodiments of the present inventive concept, the third protective pattern structure 360 may include a fifth protective pattern and a sixth protective pattern sequentially stacked in the vertical direction on the second surface 314 of the third substrate 310. A portion of the fifth protective pattern that is adjacent to the third through electrode structure 320 may protrude upwardly in the vertical direction, and an upper surface of the portion of the fifth protective pattern may be substantially coplanar with an upper surface of the third through electrode structure 320. An outer sidewall of the portion of the fifth protective pattern may be covered by the sixth protective pattern. For example, the portion of the fifth protective pattern may be disposed between the third barrier pattern 322 and the sixth protective pattern.

The fifth protective pattern may include an oxide, e.g., silicon oxide, and the sixth protective pattern may include an insulating nitride, e.g., silicon nitride.

The fifth protective pattern may have the first thickness T1 in the vertical direction, except for the portion of the fifth protective pattern adjacent to the third through electrode structure 320, and the sixth protective pattern may have the second thickness T2 in the vertical direction.

The sixth conductive pad 370 may be electrically connected to the fifth conductive pad 340 by the third through electrode structure 320 and the third wiring structure 335. In example embodiments of the present inventive concept, a plurality of sixth conductive pads 370 may be spaced apart from each other in the horizontal direction. In example embodiments of the present inventive concept, the sixth conductive pad 370 may include eleventh and twelfth seed patterns and eleventh and twelfth conductive patterns sequentially stacked upwardly in the vertical direction from the third protective pattern structure 360. In example embodiments of the present inventive concept, the twelfth conductive pattern may contact the eleventh conductive pattern, and eleventh and twelfth conductive patterns may have substantially the same planar area. For example, the twelfth conductive pattern may contact an entirety of an upper surface of the eleventh conductive pattern. Each of the eleventh and twelfth seed patterns may include, e.g., titanium and/or copper, and each of the eleventh and twelfth conductive patterns may include, e.g., nickel and/or gold.

The second conductive connection member 350 may be disposed between and contact the fourth and fifth conductive pads 270 and 340.

The fourth semiconductor chip 400 may include a fourth substrate 410 having first and second surfaces 412 and 414 that are opposite to each other in the vertical direction, a fourth through electrode structure 420 extending through the fourth substrate 410, a seventh insulating interlayer and an eighth insulating interlayer 430 sequentially stacked in the vertical direction beneath the first surface 412 of the fourth substrate 410, a seventh conductive pad 440 disposed beneath the eighth insulating interlayer 430, a fourth protective pattern structure 460 disposed on the second surface 414 of the fourth substrate 410, and an eighth conductive pad 470 disposed on the fourth protective pattern structure 460 and contacting an upper surface of the fourth through electrode structure 420.

A circuit device, e.g., a memory device may be formed beneath the first surface 412 of the fourth substrate 410. The circuit device may include circuit patterns, which may be covered by the seventh insulating interlayer. A fourth wiring structure may be disposed in the eighth insulating interlayer 430.

The seventh conductive pad 440 may be disposed under the eighth insulating interlayer 430, and may contact the fourth wiring structure to be electrically connected to the fourth wiring structure. In example embodiments of the present inventive concept, a plurality of seventh conductive pads 440 may be spaced apart from each other in the horizontal direction.

In example embodiments of the present inventive concept, the seventh conductive pad 440 may include thirteenth and fourteenth seed patterns and thirteenth and fourteenth conductive patterns sequentially stacked downwardly in the vertical direction from the eighth insulating interlayer 430. Each of the thirteenth and fourteenth seed patterns may include, e.g., titanium and/or copper, and each of the thirteenth and fourteenth conductive patterns may include, e.g., nickel and/or copper.

The fourth through electrode structure 420 may extend through the fourth substrate 410 in the vertical direction. A portion of the fourth through electrode structure 420 may protrude upwardly in the vertical direction, and may be covered by the fourth protective pattern structure 460. A plurality of fourth through electrode structures 420 may be spaced apart from each other in the horizontal direction. In example embodiments of the present inventive concept, the fourth through electrode structure 420 may include a fourth through electrode extending in the vertical direction, a fourth barrier pattern covering a sidewall of the fourth through electrode, and a fourth insulation pattern covering an outer sidewall of the fourth barrier pattern. However, in example embodiments of the present inventive concept, the fourth insulation pattern might not cover an upper portion of the outer sidewall of the fourth barrier pattern. For example, the fourth insulation pattern might not extend beyond the second surface 414 of the fourth substrate 410.

In example embodiments of the present inventive concept, the fourth through electrode structure 420 may extend through the fourth protective pattern structure 460, the fourth substrate 410 and the seventh insulating interlayer, and may contact the fourth wiring structure. The fourth through electrode structure 420 may be electrically connected to the seventh conductive pad 440 by the fourth wiring structure.

The fourth protective pattern structure 460 may be formed on the second surface 414 of the fourth substrate 410, and may surround an upper portion of the fourth through electrode structure 420. In example embodiments of the present inventive concept, the fourth protective pattern structure 460 may contact an outer sidewall of an upper portion of the fourth barrier pattern of the fourth through electrode structure 420.

In example embodiments of the present inventive concept, the fourth protective pattern structure 460 may include a seventh protective pattern and an eighth protective pattern sequentially stacked in the vertical direction on the second surface 414 of the fourth substrate 410. A portion of the seventh protective pattern that is adjacent to the fourth through electrode structure 420 may protrude upwardly in the vertical direction, and an upper surface of the portion of the seventh protective pattern may be substantially coplanar with an upper surface of the fourth through electrode structure 420. An outer sidewall of the portion of the seventh protective pattern may be covered by the eighth protective pattern. For example, the portion of the seventh protective pattern may be disposed between the eighth protective pattern and the fourth barrier pattern.

The seventh protective pattern may include an oxide, e.g., silicon oxide, and the eighth protective pattern may include an insulating nitride, e.g., silicon nitride.

The seventh protective pattern may have the first thickness T1 in the vertical direction, except for the portion of the seventh protective pattern that is adjacent to the fourth through electrode structure 420, and the eighth protective pattern may have the second thickness T2 in the vertical direction.

The eighth conductive pad 470 may be electrically connected to the seventh conductive pad 440 by the fourth through electrode structure 420 and the fourth wiring structure. In example embodiments of the present inventive concept, a plurality of eighth conductive pads 470 may be spaced apart from each other in the horizontal direction. In example embodiments of the present inventive concept, the eighth conductive pad 470 may include fifteenth and sixteenth seed patterns and fifteenth and sixteenth conductive patterns sequentially stacked upwardly in the vertical direction from the fourth protective pattern structure 460. In example embodiments of the present inventive concept, the sixteenth conductive pattern may contact the fifteenth conductive pattern, and fifteenth and the sixteenth conductive patterns may have substantially the same planar area. For example, the sixteenth conductive pattern may contact an entirety of an upper surface of the fifteenth conductive pattern. Each of the fifteenth and the sixteenth seed patterns may include, e.g., titanium and/or copper, and each of the fifteenth and the sixteenth conductive patterns may include, e.g., nickel and/or gold.

The third conductive connection member 450 may be disposed between and contact the sixth and seventh conductive pads 370 and 440.

The fifth semiconductor chip 500 may include a fifth substrate 510 having first and second surfaces 512 and 514 that are opposite to each other in the vertical direction, a ninth insulating interlayer and a tenth insulating interlayer 530 sequentially stacked in the vertical direction beneath the first surface 512 of the fifth substrate 510, and a ninth conductive pad 540 disposed beneath the tenth insulating interlayer 530.

A circuit device, e.g., a memory device may be formed beneath the first surface 512 of the fifth substrate 510. The circuit device may include circuit patterns, which may be covered by the ninth insulating interlayer. A fifth wiring structure may be disposed in the tenth insulating interlayer 530.

The ninth conductive pad 540 may be disposed under the tenth insulating interlayer 530, and may contact the fifth wiring structure to be electrically connected to be electrically connected to the fifth wiring structure. In example embodiments of the present inventive concept, a plurality of ninth conductive pads 540 may be spaced apart from each other in the horizontal direction.

In example embodiments of the present inventive concept, the ninth conductive pad 540 may include seventeenth and eighteenth seed patterns and seventeenth and eighteenth conductive patterns sequentially stacked downwardly in the vertical direction from the tenth insulating interlayer 530. Each of the seventeenth and eighteenth seed patterns may include, e.g., titanium and/or copper, and each of the seventeenth and eighteenth conductive patterns may include, e.g., nickel and/or copper.

The fourth conductive connection member 550 may be disposed between and contact the eighth and ninth conductive pads 470 and 540.

The first to fifth semiconductor chips 100, 200, 300, 400 and 500 may be electrically connected to each other by the first to fourth through electrodes 120, 220, 320 and 420 extending through the first to fourth substrates 110, 210, 310 and 410, respectively, the first to third wiring structures 135, 235 and 335 and the fourth and fifth wiring structures electrically connected thereto, the first to ninth conductive pads 140, 170, 240, 270, 340, 370, 440, 470 and 540 electrically connected thereto, and the first to fourth conductive connection members 250, 350, 450 and 550 electrically connected thereto, and electrical signals, e.g., data signals, control signals, etc., may be transferred to each other.

Additionally, the fifth conductive connection member 180 may contact the first conductive pad 140, and electrical signals may be transferred from the first conductive pad 140 to an external device. The first conductive connection member 250 may be, e.g., a conductive ball. The fifth conductive connection member 180 may include a metal, e.g., tin, or an alloy of tin/silver, tin/copper, tin/indium, tin/silver/copper, etc.

The molding member 600 may cover sidewalls of the second to fifth semiconductor chips 200, 300, 400 and 500 and may be disposed on the first semiconductor chip 100, and an upper surface of the molding member 600 may be substantially coplanar with an upper surface of the fifth semiconductor chip 500. The molding member 600 may include a polymer, e.g., epoxy molding compound (EMC).

In the semiconductor package according to embodiments of the present inventive concept, the first to fifth semiconductor chips 100, 200, 300, 400 and 500 may communicate with each other through the first to fourth conductive connection members 250, 350, 450 and 550. For example, the first conductive connection member 250 may be disposed between and contact the second and third conductive pads 170 and 240 of the first and second semiconductor chips 100 and 200, respectively, and thus may serve as an electrical signal path. Additionally, the second conductive connection member 350 may be disposed between and contact the fourth and fifth conductive pads 270 and 340 of the second and third semiconductor chips 200 and 300, respectively, and thus may serve as an electrical signal path.

The third conductive pad 240 may include the fifth and sixth seed patterns 241 and 242 and the fifth and sixth conductive patterns 245 and 246 sequentially stacked in the vertical direction. The sixth conductive pattern 246 including, e.g., copper may be disposed between the fifth conductive pattern 245 including, e.g., nickel and the first conductive connection member 250 including, e.g., solder, and may increase the adhesion therebetween. Additionally, the second conductive pad 170 may include the third and fourth seed patterns 171 and 172 and the third and fourth conductive patterns 175 and 176 sequentially stacked in the vertical direction. The fourth conductive pattern 176 including, e.g., gold may contact the third conductive pattern 175. For example, the fourth conductive pattern 176 may contact an entirety of an upper surface of the third conductive pattern 175. The fourth conductive pattern 176 may be disposed between the first conductive connection member 250 including, e.g., solder and the third conductive pattern 175, and may increase the adhesion therebetween.

Likewise, the fifth conductive pad 340 may include the ninth and tenth seed patterns 341 and 342 and the ninth and tenth conductive patterns 345 and 346 sequentially stacked in the vertical direction. The tenth conductive pattern 346 including, e.g., copper may be disposed between the ninth conductive pattern 345 including, e.g., nickel and the second conductive connection member 350 including, e.g., solder, and may increase the adhesion therebetween. Additionally, the fourth conductive pad 270 may include the seventh and eighth seed patterns 271 and 272 and the seventh and eighth conductive patterns 275 and 276 sequentially stacked in the vertical direction. The eighth conductive pattern 276 including, e.g., gold may contact the seventh conductive pattern 275. For example, the eighth conductive pattern 276 may contact an entirety of an upper surface of the seventh conductive pattern 275. The eighth conductive pattern 276 may be disposed between the second conductive connection member 350 including, e.g., solder and the seventh conductive pattern 275, and may increase the adhesion therebetween.

Accordingly, the electrical signal transfer between the second and third conductive pads 170 and 240 through the first conductive connection member 250, and the electrical signal transfer between the fourth and fifth conductive pads 270 and 340 through the second conductive connection member 350 may be well performed, so that the semiconductor package according to embodiments of the present inventive concept including the first and second conductive connection members 250 and 350 may have enhanced electrical characteristics.

In the semiconductor package according to embodiments of the present inventive concept, each of the bonding layers 700 may at least partially surround a corresponding one of the first to fourth conductive connection members 250, 350, 450 and 550, and may be disposed between neighboring ones of the first to fifth semiconductor chips 100, 200, 300, 400 and 500 to bond the first to fifth semiconductor chips 100, 200, 300, 400 and 500 with each other. The bonding layer 700 may have a poor characteristic of heat emission, and thus, if the bonding layer 700 has a large vertical thickness, the characteristic of heat emission of the semiconductor package including the bonding layer 700 may be deteriorated. In example embodiments of the present inventive concept, each of the bonding layers 700 may have a thickness in a range of about 6.0 um to about 8.0 um, for example, in a range of about 6.0 um to about 7.0 um.

In the semiconductor package according to embodiments of the present inventive concept, the first to fourth protective pattern structures 160, 260 360 and 460 may at least partially surround and protect upper sidewalls of the first to fourth through electrode structures 120, 220, 320 and 420, respectively. However, each of the first to fourth protective pattern structures 160, 260, 360 and 460 may have a relatively poor heat emission characteristic, and thus, if each of the first to fourth protective pattern structures 160, 260, 360 and 460 has a large vertical thickness, the heat emission characteristic of the semiconductor package may be deteriorated.

Thus, each of the first to fourth protective pattern structures 160, 260, 360 and 460 may have a small thickness in a range of about 0.85 um to about 1.65 um. For example, in the first protective pattern structure 160, the second protective pattern 162 may have a thickness of about 0.35 um, and the first protective pattern 161 may have a thickness in a range of about 0.5 um to about 1.3 um. For example, a thickness ratio of the first protective pattern 161 with respect to the second protective pattern 162 may be in a range of about 1.4 to about 3.7.

Additionally, in the second protective pattern structure 260, the fourth protective pattern 262 may have a thickness of about 0.35 um, and the third protective pattern 261 may have a thickness in a range of about 0.5 um to about 1.3 um. For example, a thickness ratio of the third protective pattern 261 with respect to the fourth protective pattern 262 may be in a range of about 1.4 to about 3.7.

In the third protective pattern structure 360, the sixth protective pattern may have a thickness of about 0.35 um, and the fifth protective pattern may have a thickness in a range of about 0.5 um to about 1.3 um. For example, a thickness ratio of the fifth protective pattern with respect to the sixth protective pattern may be in a range of about 1.4 to about 3.7.

In the fourth protective pattern structure 460, the eighth protective pattern may have a thickness of about 0.35 um, and the seventh protective pattern may have a thickness in a range of about 0.5 um to about 1.3 um. For example, a thickness ratio of the seventh protective pattern with respect to the eighth protective pattern maybe in a range of about 1.4 to about 3.7.

In the semiconductor package according to embodiments of the present inventive concept, as the bonding layer 700 and the each of the first to fourth protective pattern structures 160, 260, 360 and 460 have the small thickness, the semiconductor package may have an enhanced emission characteristic. In a comparative example, the bonding layer 700 had a thickness of about 9.0 um and each of the first to fourth protective pattern structures 160, 260, 360 and 460 had a thickness of about 2.15 um, and the heat emission was about 1.01° C./W. In example embodiments of the present inventive concept, the bonding layer 700 had a thickness of about 7.0 um and each of the first to fourth protective pattern structures 160, 260, 360 and 460 had a thickness of about 1.15 um, and the heat emission was about 0.804° C./W.

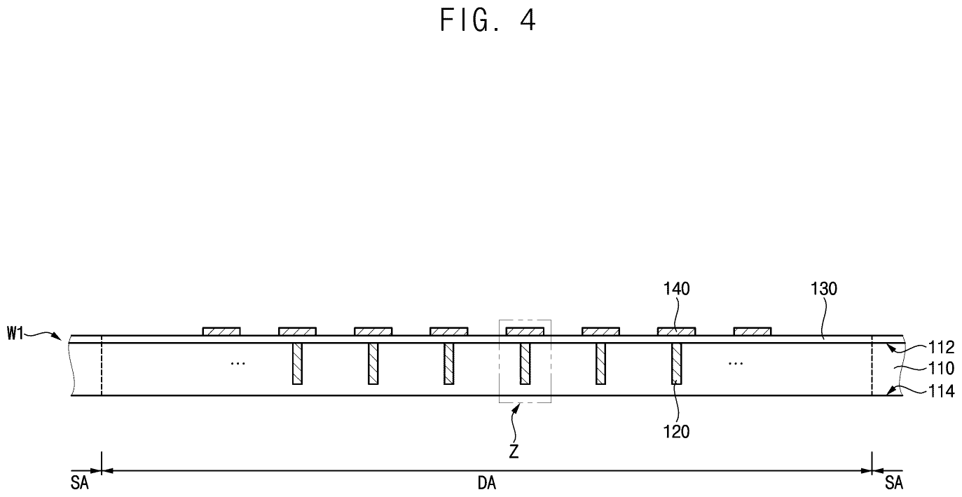

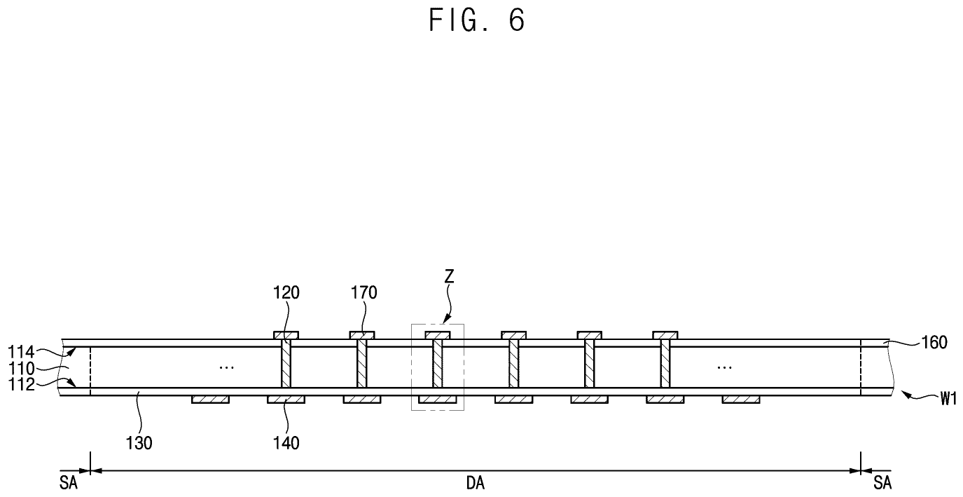

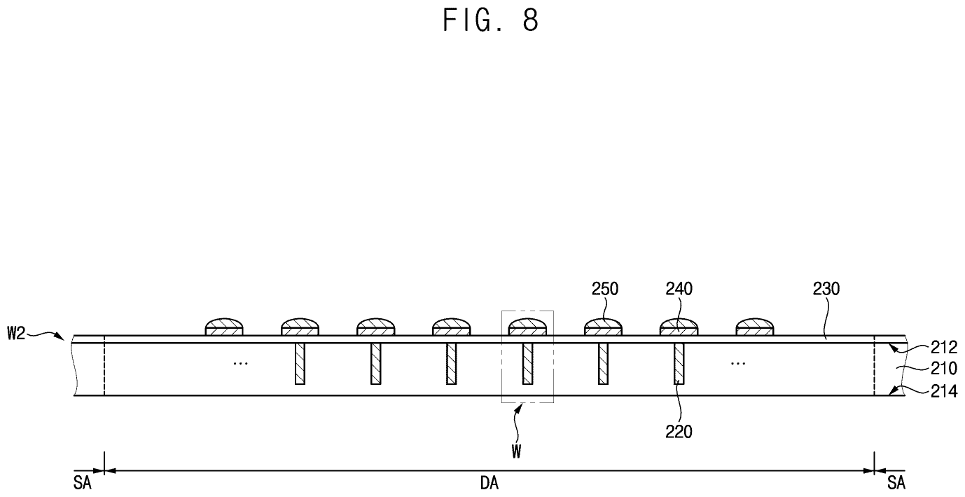

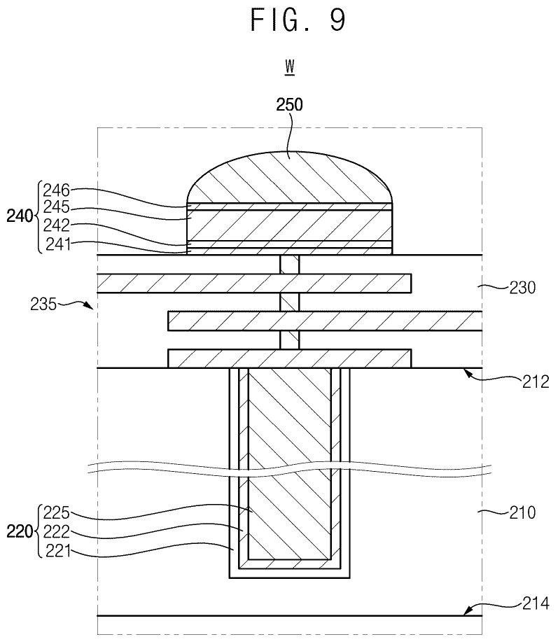

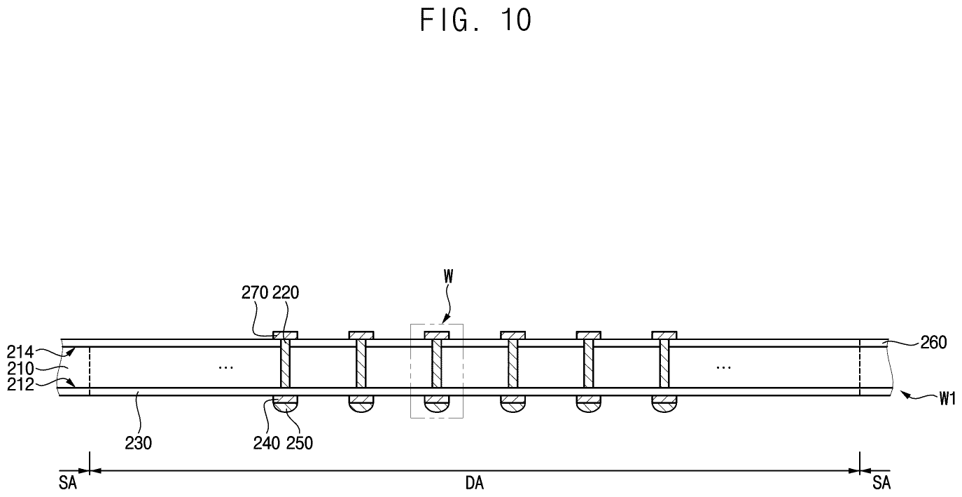

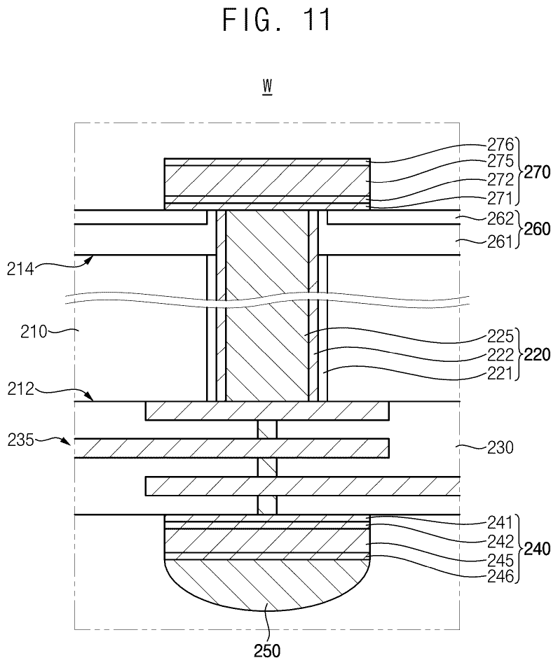

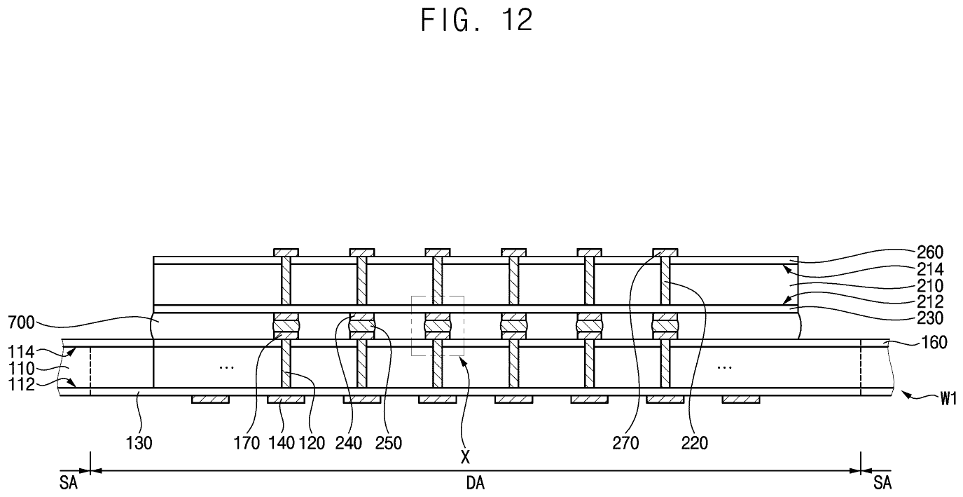

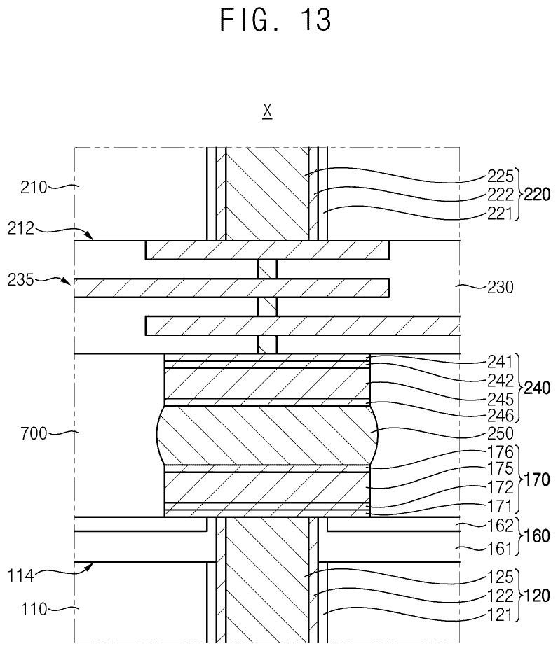

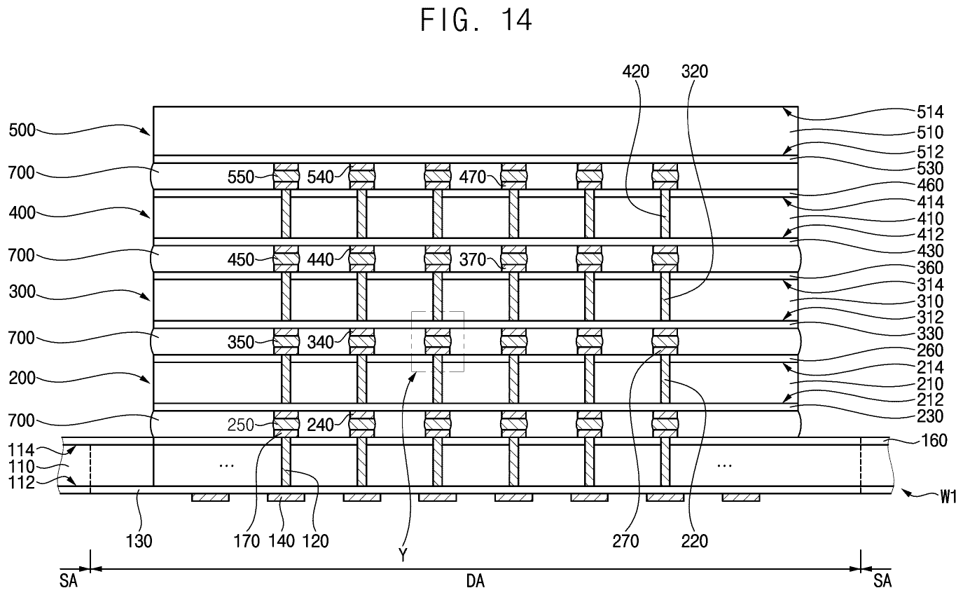

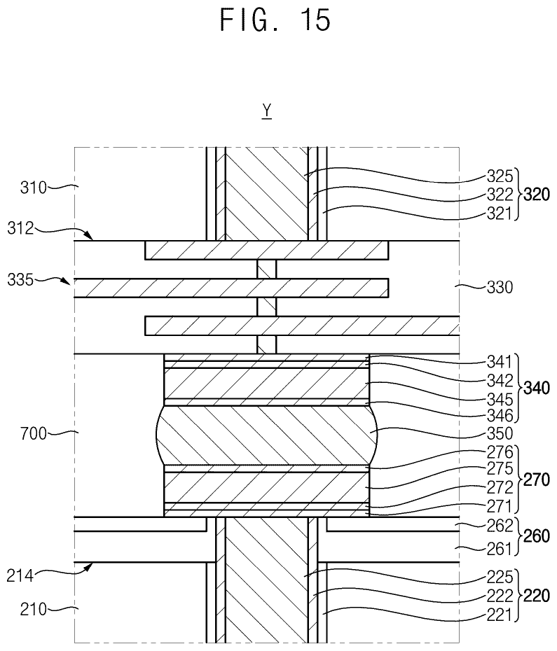

FIGS. 4 to 16 are cross-sectional views illustrating a method of manufacturing a semiconductor package according to example embodiments of the present inventive concept. FIGS. 5 and 7 are enlarged cross-sectional views of region Z of FIGS. 4 and 6, respectively. FIGS. 9 and 11 are enlarged cross-sectional views of region W of FIGS. 8 and 10, respectively. FIG. 13 is an enlarged cross-sectional view of region X of FIG. 12, and FIG. 15 is an enlarged cross-sectional view of region Y of FIG. 14.

Referring to FIGS. 4 and 5, a first wafer W1 may be provided.

In example embodiments of the present inventive concept, the first wafer W1 may include a first substrate 110 having first and second surfaces 112 and 114 that are opposite to each other in the vertical direction. Additionally, the first wafer W1 may include a plurality of die regions DA and a scribe lane region S1 at least partially surrounding each of the die regions DA. The first wafer W1 may be cut along the scribe lane region SA by a sawing process to be singulated into a plurality of first semiconductor chips.

In the die region DA, a circuit device may be formed beneath the first surface 112 of the first substrate 110. The circuit device may include a logic device. The circuit device may include circuit patterns, and a first insulating interlayer may be formed on the first surface 112 of the first substrate 110 to cover the circuit patterns.

A second insulating interlayer 130 may be formed on the first insulating interlayer, and a first wiring structure 135 may be disposed in the second insulating interlayer 130. The first wiring structure 135 may include, e.g., wirings, vias, contact plugs, etc.

A first conductive pad 140 may be formed on second insulating interlayer 130 to contact the first wiring structure 135 and to be electrically connected to the first wiring structure 135. In example embodiments of the present inventive concept, a plurality of first conductive pads 140 may be spaced apart from each other in the horizontal direction.

In example embodiments of the present inventive concept, the first conductive pad 140 may be formed by following processes.

First and second seed layers may be sequentially formed on the second insulating interlayer 130, a first photoresist pattern including a first opening partially exposing an upper surface of the second seed layer may be formed on the second seed layer, and an electroplating process or an electroless plating process may be performed to form first and second conductive patterns 145 and 146 in the first opening.

The first photoresist pattern may be removed by, e.g., an ashing process and/or a stripping process to expose a portion of the second seed layer, the exposed portion of the second seed layer and a portion of the first seed layer thereunder may be removed to form a second seed pattern 142 and a first seed pattern 141, respectively, under the first conductive pattern 145.

Thus, a first conductive pad 140 including the first and second seed patterns 141 and 142 and the first and second conductive patterns 145 and 146 sequentially stacked in the vertical direction may be formed.

In example embodiments of the present inventive concept, each of the first and second seed patterns 141 and 142 may include titanium and/or copper, and each of the first and second conductive patterns 145 and 146 may include nickel and/or copper.

In example embodiments of the present inventive concept, a first through electrode structure 120 extending through the first substrate 110 in the vertical direction may be formed. In example embodiments of the present inventive concept, a plurality of first through electrode structures 120 may be spaced apart from each other in the horizontal direction.

In example embodiments of the present inventive concept, the first through electrode structure 120 may include a first through electrode 125 extending in the vertical direction, a first barrier pattern 122 covering a sidewall and a lower surface of the first through electrode 125, and a first insulation pattern 121 covering a sidewall and a lower surface of the first barrier pattern 122.

Referring to FIGS. 6 and 7, after turning over the first wafer W1, a portion of the first substrate 110 adjacent to the second surface 114 of the first substrate 110 may be removed by, e.g., a grinding process to expose an upper portion of the first through electrode structure 120.

In example embodiments of the present inventive concept, an upper portion of the first insulation pattern 121 of the first through electrode structure 120 may also be removed by the grinding process, and thus an upper outer sidewall of the first barrier pattern 122 may be exposed.

A first protective layer structure may be formed on the second surface 114 of the first substrate 110 to cover the first through electrode structure 120, and a planarization process may be performed on the first protective layer structure until an upper surface of the first through electrode 125 of the first through electrode structure 120 is exposed to form a first protective pattern structure 160.

In example embodiments of the present inventive concept, the planarization process may include a chemical mechanical polishing (CMP) process and/or an etch back process.

In example embodiments of the present inventive concept, the first protective layer structure may include first to third protective layers sequentially stacked in the vertical direction, and during the planarization process, the third protective layer may be removed and the second protective layer may partially remain. Thus, the first protective pattern structure 160 may include first and second protective patterns 161 and 162 sequentially stacked in the vertical direction. An upper outer sidewall of a portion of the first protective pattern 161 that is adjacent to the first through electrode structure 120 may be covered by the second protective pattern 162.

A second conductive pad 170 may be formed on the first protective pattern structure 160 and the first through electrode structure 120. In example embodiments of the present inventive concept, a plurality of second conductive pads 170 may be spaced apart from each other in the horizontal direction, and each of the second conductive pads 170 may contact an upper surface of the first through electrode structure 120 to be electrically connected to the first through electrode structure 120.

In example embodiments of the present inventive concept, the second conductive pad 170 may be formed by following processes.

Third and fourth seed layers may be sequentially formed on the first protective pattern structure 160 and the first through electrode structure 120. Further, a second photoresist pattern including a second opening partially exposing an upper surface of the fourth seed layer may be formed on the fourth seed layer, and an electroplating process or an electroless plating process may be performed to form third and fourth conductive patterns 175 and 176 in the second opening.

The second photoresist pattern may be removed by, e.g., an ashing process and/or a stripping process to expose a portion of the fourth seed layer, and the exposed portion of the fourth seed layer and a portion of the third seed layer thereunder may be removed to form a fourth seed pattern 172 and a third seed pattern 171, respectively, under the third conductive pattern 175.

Thus, a second conductive pad 170 including the third and fourth seed patterns 171 and 172 and the third and fourth conductive patterns 175 and 176 sequentially stacked in the vertical direction may be formed.

In example embodiments of the present inventive concept, each of the third and fourth seed patterns 171 and 172 may include titanium and/or copper, and each of the third and fourth conductive patterns 175 and 176 may include nickel and/or gold.

Referring to FIG. 8, a second wafer W2 may be provided.

In example embodiments of the present inventive concept, the second wafer W2 may include a second substrate 210 having first and second surfaces 212 and 214 that are opposite to each other in the vertical direction. Additionally, the second wafer W2 may include a plurality of die regions DA and a scribe lane region S1 at least partially surrounding each of the die regions DA. The second wafer W2 may be cut along the scribe lane region SA by a sawing process to be singulated into a plurality of second semiconductor chips.

In the die region DA, a circuit device may be formed beneath the first surface 212 of the second substrate 210. The circuit device may include, e.g., a volatile memory device such as a DRAM device, an SRAM device, etc., or a non-volatile memory device such as a flash memory device, an EEPROM device, etc. The circuit device may include circuit patterns, and a third insulating interlayer may be formed on the first surface 212 of the second substrate 210 to cover the circuit patterns.

A fourth insulating interlayer 230 may be formed on the third insulating interlayer, and may include a second wiring structure 235 therein. The second wiring structure 235 may include, e.g., wirings, vias, contact plugs, etc.

A third conductive pad 240 may be formed on fourth insulating interlayer 230 to contact the second wiring structure 235 and to be electrically connected to the second wiring structure 235. In example embodiments of the present inventive concept, a plurality of third conductive pads 240 may be spaced apart from each other in the horizontal direction.

In example embodiments of the present inventive concept, the third conductive pad 240 may be formed by processes substantially the same as or similar to those of the first conductive pad 140. Thus, a third conductive pad 240 including fifth and sixth seed patterns 241 and 242 and the fifth and sixth conductive patterns 245 and 246 sequentially stacked in the vertical direction may be formed.

In example embodiments of the present inventive concept, each of the fifth and sixth seed patterns 241 and 242 may include titanium and/or copper, and each of the fifth and sixth conductive patterns 245 and 246 may include nickel and/or copper.

A first conductive connection member 250 may be formed on the third conductive pad 240.

In example embodiments of the present inventive concept, the first conductive connection member 250 may be formed by following processes.

A third photoresist pattern including a third opening exposing an upper surface of the third conductive pad 240 may be formed on the fourth insulating interlayer 230, and an electroplating process or an electroless plating process may be performed to form a preliminary first conductive connection member in the third opening. After removing the third photoresist pattern, a reflow process may be performed so that the preliminary first conductive connection member may be transformed into a first conductive connection member 250.

In example embodiments of the present inventive concept, the first conductive connection member 250 may have a shape of, e.g., a semi-circle or a semi-ellipse.

In example embodiments of the present inventive concept, a second through electrode structure 220 extending through the second substrate 210 in the vertical direction may be formed. In example embodiments of the present inventive concept, a plurality of second through electrode structures 220 may be spaced apart from each other in the horizontal direction.

In example embodiments of the present inventive concept, the second through electrode structure 220 may include a second through electrode 225 extending in the vertical direction, a second barrier pattern 222 covering a sidewall and a lower surface of the second through electrode 225, and a second insulation pattern 221 covering a sidewall and a lower surface of the second barrier pattern 222.

Referring to FIGS. 10 and 11, after turning over the second wafer W2, a portion of the second substrate 210 adjacent to the second surface 214 of the second substrate 210 may be removed by, e.g., a grinding process to expose an upper portion of the second through electrode structure 220.

In example embodiments of the present inventive concept, an upper portion of the second insulation pattern 221 of the second through electrode structure 220 may also be removed by the grinding process, and thus, an upper outer sidewall of the second barrier pattern 222 may be exposed.

A second protective layer structure may be formed on the second surface 214 of the second substrate 210 to cover the second through electrode structure 220, and a planarization process may be performed on the second protective layer structure until an upper surface of the second through electrode 225 of the second through electrode structure 220 is exposed to form a second protective pattern structure 260.

In example embodiments of the present inventive concept, the planarization process may include a chemical mechanical polishing (CMP) process and/or an etch back process.

In example embodiments of the present inventive concept, the second protective layer structure may have a structure substantially the same as or similar to that of the first protective layer structure, and thus, a second protective pattern structure may include third and fourth protective patterns 261 and 262 sequentially stacked in the vertical direction. An upper outer sidewall of a portion of the third protective pattern 261 that is adjacent to the second through electrode structure 220 may be covered by the fourth protective pattern 262.

A fourth conductive pad 270 may be formed on the second protective pattern structure 260 and the second through electrode structure 220. In example embodiments of the present inventive concept, a plurality of fourth conductive pads 270 may be spaced apart from each other in the horizontal direction, and each of the fourth conductive pads 270 may contact an upper surface of the second through electrode structure 220 to be electrically connected to the second through electrode structure 220.

In an example embodiment of the present inventive concept, the fourth conductive pad 270 may be formed by processes substantially the same as or similar to that of the second conductive pad 170. Thus, the fourth conductive pad 270 including seventh and eighth seed patterns 271 and 272 and seventh and eighth conductive patterns 275 and 276 may be formed.

In example embodiments of the present inventive concept, each of the seventh and eighth seed patterns 271 and 272 may include titanium and/or copper, and each of the seventh and eighth conductive patterns 275 and 276 may include nickel and/or gold.

Referring to FIGS. 12 and 13, after cutting the wafer W2 along the scribe lane region SA by a sawing process to form second semiconductor chips 200, a bonding layer 700 may be formed on the fourth insulating interlayer 230 of each of the second semiconductor chips 200.

The bonding layer 700 may be formed on the fourth insulating interlayer 230 to cover the third conductive pad 240 and the first conductive connection member 250. The bonding layer 700 may include a NCF, e.g., thermosetting resin.

In example embodiments of the present inventive concept, the bonding layer 700 may be formed on the fourth insulating interlayer 230 of the second wafer W2, before the sawing process.

Each of the second semiconductor chips 200 may be mounted on the first wafer W1 such that the bonding layer 700 on each of the semiconductor chips 200 may contact an upper surface of the first protective pattern structure 160 that is on the first wafer W1. The second semiconductor chips 200 may be disposed on the respective die regions DA of the first wafer W1, and the first conductive connection member 250 of the second semiconductor chip 200 may contact an upper surface of the second conductive pad 170 of the first semiconductor chip 100.

A thermal pressing process may be performed at a temperature equal to or less than about 400° C. so that the second semiconductor chips 200 may be bonded to the first wafer W1. During the thermal pression process, the NCF included in the bonding layer 700 may be melted to have fluidity, and may flow in a space between the second semiconductor chips 200 and the first wafer W1. The NCF may be cured to fill the space, and a portion of the NCF may protrude beyond a sidewall of each of the second semiconductor chips 200.

By the thermal pressing process, the first conductive connection member 250 of the second semiconductor chip 200 may be bonded with the second conductive pad 170 of the first semiconductor chip 100.

Referring to FIGS. 14 and 15, third to fifth semiconductor chips 300, 400 and 500 may be sequentially stacked on the second semiconductor chip 200.

Processes substantially the same as or similar to those illustrated with respect to FIGS. 8 to 13 may be performed to form a plurality of third semiconductor chips 300, and processes substantially the same as or similar to those illustrated with respect to FIGS. 12 and 13 may be performed so that the third semiconductor chip 300 may be stacked on the second semiconductor chip 200.

In example embodiments of the present inventive concept, the third semiconductor chip 300 may include a third substrate 310 having first and second surfaces 312 and 314 that are opposite to each other in the vertical direction, and may be stacked on the second semiconductor chip 200 such that the bonding layer 700 covering a sixth insulating interlayer 330, which is disposed on the first surface 312 of the third substrate 310, may contact the second protective pattern structure 260, which is disposed on the second surface 214 of the second substrate 210. The second conductive connection member 350 of the third semiconductor chip 300 may be bonded with the fourth conductive pad 270 of the second semiconductor chip 200.

Likewise, the fourth semiconductor chip 400 including a fourth substrate 410 having first and second surfaces 412 and 414 that are opposite to each other in the vertical direction may be stacked on the third semiconductor chip 300, and the fifth semiconductor chip 500 including a fifth substrate 510 having first and second surfaces 512 and 514 that are opposite to each other in the vertical direction may be stacked on the fourth semiconductor chip 400.

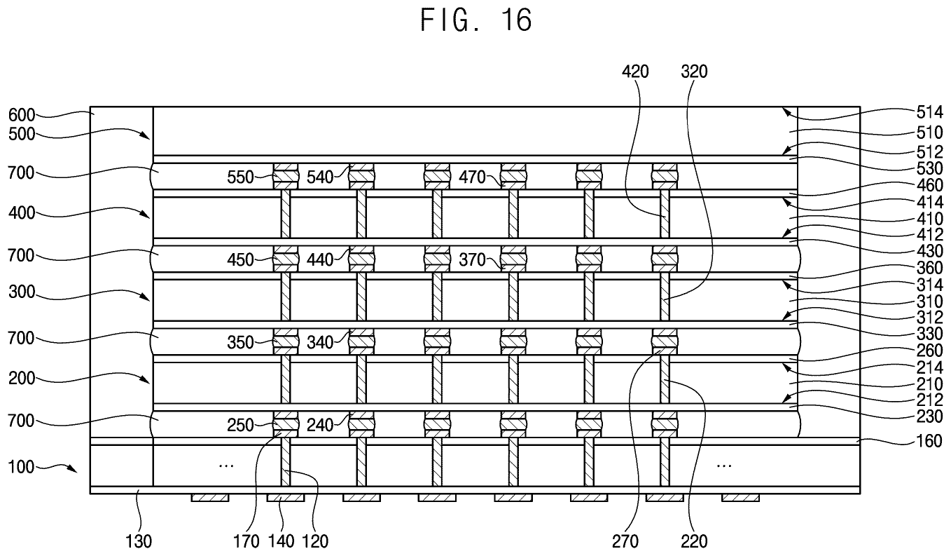

Referring to FIG. 16, a molding member 600 may be formed on the first wafer W1 to fill a space between structures each of which may include the second to fifth semiconductor chips 200, 300, 400 and 500.

In example embodiments of the present inventive concept, the molding member 600 may expose an upper surface of the fifth semiconductor chip 500.

Referring to FIGS. 1 to 3 again, a fifth conductive connection member 180 may be formed on a lower surface of the first conductive pad 140 that is disposed beneath the second insulating interlayer 130 of the first semiconductor chip 100, and the first wafer W1 may be cut along the scribe lane region SA by, e.g., a sawing process to be singulated into a plurality of first semiconductor chips 100. For example, the fifth conductive connection member 180 may contact the lower surface of the first conductive pad 140.

During the sawing process, the molding member 600 may also be cut to cover sidewalls of the second to fifth semiconductor chips 200, 300, 400 and 500 on each of the first semiconductor chips 100.

The semiconductor package may be manufactured by the above processes.

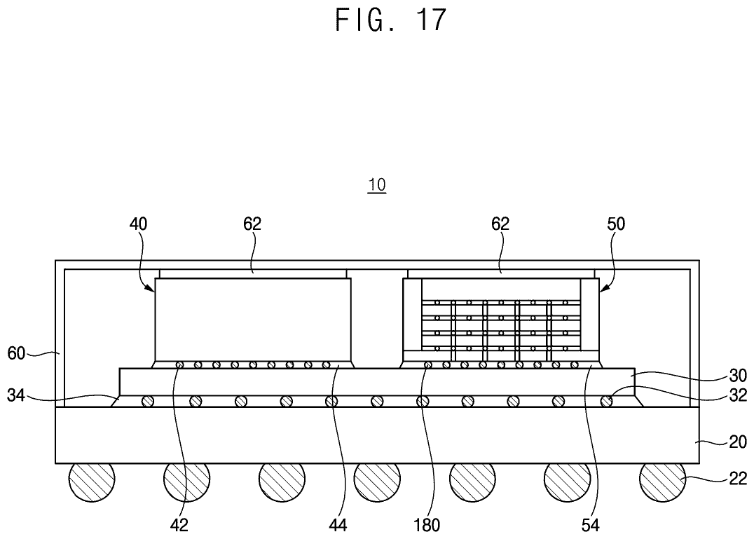

FIG. 17 is a cross-sectional view illustrating an electronic device according to example embodiments of the present inventive concept.

This electronic device may include the semiconductor package shown in FIGS. 1 to 3 as a second semiconductor device 50, however, the present inventive concept might not necessarily be limited thereto.

Referring to FIG. 17, an electronic device 10 may include a package substrate 20, an interposer 30, a first semiconductor device 40 and the second semiconductor device 50. The electronic device 10 may further include first, second and third underfill members 34, 44 and 54, a heat slug 60 and a heat dissipation member 62.

In example embodiments of the present inventive concept, the electronic device 10 may be a memory module having a 2.5D package structure, and thus, may include the interposer 30 for electrically connecting the first and second semiconductor devices 40 and 50 to each other.

In example embodiments of the present inventive concept, the first semiconductor device 40 may include a logic device, and the second semiconductor device 50 may include a memory device. The logic device may be an application-specific integrated circuit (ASIC) chip including, e.g., a central processing unit (CPU), a graphics processing unit (GPU), a micro-processor, a micro-controller, an application processor (AP), a digital signal processing core, etc. The memory device may be the semiconductor package of FIGS. 1 to 3.

In example embodiments of the present inventive concept, the package substrate 20 may have an upper surface and a lower surface that are opposite to each other in the vertical direction. For example, the package substrate 20 may be a printed circuit board (PCB). The printed circuit board may be a multi-layer circuit board having various circuits therein. The interposer 30 may be mounted on the package substrate 20 through a seventh conductive connection member 32. In example embodiments of the present inventive concept, a planar area of the interposer 30 may be smaller than a planar area of the package substrate 20. The interposer 30 may be disposed within an area of the package substrate 20 in a plan view.

The interposer 30 may be a silicon interposer or a redistribution interposer having a plurality of wirings therein. The first semiconductor device 40 and the second semiconductor device 50 may be connected to each other through the wirings in the interposer 30 and/or electrically connected to the package substrate 20 through the seventh conductive connection member 32. The seventh conductive connection member 32 may include, e.g., a micro-bump. The silicon interposer may provide a high-density interconnection between the first and second semiconductor devices 40 and 50.

The first semiconductor device 40 may be disposed on the interposer 30. The first semiconductor device 40 may be mounted on and bonded with the interposer 30 by a flip chip bonding process. In this case, the first semiconductor device 40 may be mounted on the interposer 30 such that an active surface on which conductive pads are formed may face downwardly toward the interposer 30. The conductive pads of the first semiconductor device 40 may be electrically connected to conductive pads of the interposer 30 through an eighth conductive connection member 42. For example, the eighth conductive connection member 42 may include, e.g., a micro-bump.

In addition, the first semiconductor device 40 may be mounted on the interposer 30 by a wire bonding process, and in this case, the active surface of the first semiconductor device 40 may face upwardly.

The second semiconductor device 50 may be disposed on the interposer 30, and may be spaced apart from the first semiconductor device 40 in the horizontal direction. The second semiconductor device 50 may be mounted on and bonded with the interposer 30 by, e.g., a flip chip bonding process. In this case, conductive pads of the second semiconductor device 50 may be electrically connected to conductive pads of the interposer 30 by the fifth conductive connection member 180.

Although a single first semiconductor device 40 and a single second semiconductor device 50 are disposed on the interposer 30, the present inventive concept might not necessarily be limited thereto, and a plurality of first semiconductor devices 40 and/or a plurality of second conductive devices 50 may be disposed on the interposer 30.

In example embodiments of the present inventive concept, the first underfill member 34 may fill a space between the interposer 30 and the package substrate 20, and the second and third underfill members 44 and 54 may fill a space between the first semiconductor device 40 and the interposer 30 and a space between the second semiconductor device 50 and the interposer 30, respectively.

The first to third underfill members 34, 44 and 54 may include a material having a relatively high fluidity to effectively fill a small space between the first and second semiconductor devices 40 and 50 and the interposer 30 and a small space between the interposer 30 and the package substrate 20. For example, each of the first and second underfill members34, 44 and 54 may include an adhesive including an epoxy material.

The semiconductor device 50 may include a buffer die and a plurality of memory dies sequentially stacked on the buffer die. The buffer die and the memory dies may be electrically connected to each other by through electrodes, e.g., TSVs, and the through electrodes may be electrically connected to each other by conductive connection members. Data signals and control signals may be transferred to the buffer die and the memory dies by the through electrodes.

In example embodiments of the present inventive concept, the heat slug 60 be formed on the package substrate 20 to thermally contact the first and second semiconductor devices 40 and 50. The heat dissipation member 62 may be disposed on an upper surface of each of the first and second semiconductor devices 40 and 50, and may include, e.g., thermal interface material (TIM). The heat slug 60 may thermally contact the first and second semiconductor devices 40 and 50 via the heat dissipation member 62.

A conductive pad may be formed at a lower portion of the package substrate 20, and a sixth conductive connection member 22 may be disposed beneath the conductive pad. In example embodiments of the present inventive concept, a plurality of sixth conductive connection members 22 may be spaced apart from each other in the horizontal direction. The sixth conductive connection member 22 may be, e.g., a solder ball. The electronic device 10 may be mounted on a module board via the sixth conductive connection members 22 to form a memory module.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor package comprising:
a buffer die;
memory dies sequentially stacked on the buffer die;
a bonding layer disposed between neighboring ones of the memory dies, wherein the bonding layer bonds the neighboring ones of the memory dies with each other; and
a molding member disposed on the buffer die, wherein the molding member covers sidewalls of the memory dies,
wherein:
each of the memory dies includes:
a first substrate having first and second surfaces that are opposite to each other in a vertical direction substantially perpendicular to an upper surface of the buffer die;
a first conductive pad and a first conductive connection member that are stacked on the first surface of the first substrate; and
a second conductive pad disposed on the second surface of the first substrate,
wherein the second conductive pad of a first memory die of the memory dies contacts the first conductive connection member of a second memory die of the memory dies, wherein the first memory die is disposed under the second memory die,
wherein the first conductive pad includes a first conductive pattern and a second conductive pattern sequentially stacked downwardly in the vertical direction,
wherein the second conductive pad includes a third conductive pattern and a fourth conductive pattern sequentially stacked upwardly in the vertical direction,
wherein the fourth conductive pattern contacts the third conductive pattern, and
wherein each of the first and third conductive patterns includes nickel, wherein the second conductive pattern includes copper, and the fourth conductive pattern includes gold.

2. The semiconductor package of claim 1, wherein the first conductive pad further includes a first seed pattern and a second seed pattern stacked downwardly in the vertical direction, wherein the first conductive pattern is disposed beneath the second seed pattern, and
wherein the first seed pattern includes titanium, and the second seed pattern includes copper.

3. The semiconductor package of claim 2, wherein the second conductive pad further includes a third seed pattern and a fourth seed pattern stacked upwardly in the vertical direction, wherein the third conductive pattern is disposed on the fourth seed pattern, and
wherein the third seed pattern includes titanium, and the fourth seed pattern includes copper.

4. The semiconductor package of claim 1, wherein the first conductive connection member includes solder.

5. The semiconductor package of claim 1, wherein the buffer die includes:
a second substrate having first and second surfaces that are opposite to each other in the vertical direction;
a third conductive pad and a second conductive connection member that are stacked beneath the first surface of the second substrate in the vertical direction; and
a fourth conductive pad disposed on the second surface of the second substrate, and
wherein the fourth conductive pad of the buffer die contacts the first conductive connection member of a lowermost memory die of the memory dies.

6. The semiconductor package of claim 5, wherein the third conductive pad includes a fifth conductive pattern and a sixth conductive pattern stacked downwardly in the vertical direction,
the fourth conductive pad includes a seventh conductive pattern and an eighth conductive pattern stacked upwardly in the vertical direction,
each of the fifth and seventh conductive patterns includes nickel,
the sixth conductive pattern includes copper, and
the eighth conductive pattern includes gold.

7. The semiconductor package of claim 1, wherein each of the memory dies includes:
a through electrode structure extending through the first substrate, wherein a portion of the through electrode structure beyond the second surface of the first substrate; and
a protective pattern structure disposed on the second surface of the first substrate, wherein the protective pattern structure covers a sidewall of the portion of the through electrode structure.

8. The semiconductor package of claim 7, wherein the protective pattern structure includes:
a first protective pattern including silicon oxide; and
a second protective pattern disposed on the first protective pattern, and including silicon nitride.

9. The semiconductor package of claim 8, wherein a thickness in the vertical direction of the first protective pattern, except for a portion of the first protective pattern that is adjacent to the through electrode structure, is in a range of about 0.5 um to about 1.3 um.

10. The semiconductor package of claim 1, wherein a thickness in the vertical direction of the bonding layer is in a range of about 6.0 um to about 7.0 um.

11. A semiconductor package comprising:
a buffer die;
memory dies stacked on the buffer die;
a bonding layer disposed between neighboring ones of the memory dies, wherein the bonding layer bonds the neighboring ones of the memory dies with each other; and
a molding member disposed on the buffer die, wherein the molding member covers sidewalls of the memory dies,
wherein:
each of the memory dies includes:
a substrate having first and second surfaces that are opposite to each other in a vertical direction substantially perpendicular to an upper surface of the buffer die;
a through electrode structure extending through the substrate, wherein a portion of the through electrode structure protrudes beyond the second surface of the substrate;
a protective pattern structure including:
a first protective pattern; and
a second protective pattern disposed on the first protective pattern;
a first conductive pad and a conductive connection member that are stacked on the first surface of the first substrate; and
a second conductive pad disposed on the protective pattern structure, wherein the second conductive pad contacts the through electrode structure,
wherein the second conductive pad of a first memory die of the memory dies contacts the conductive connection member of a second memory die of the memory dies, wherein the first memory die is disposed under the second memory die,
wherein the bonding layer has a thickness of about 6.0 um to about 7.0 um, and
wherein the first protective pattern has a thickness of about 0.5 um to about 1.3 um.

12. The semiconductor package of claim 11, wherein a ratio of a thickness of the first protective pattern with respect to a thickness of the second protective pattern is about 1.4 to about 3.7.

13. The semiconductor package of claim 11, wherein the first conductive pad includes a first conductive pattern and a second conductive pattern stacked downwardly in the vertical direction,
the second conductive pad includes a third conductive pattern and a fourth conductive pattern stacked upwardly in the vertical direction,
each of the first and third conductive patterns includes nickel, wherein the second conductive pattern includes copper, and the fourth conductive pattern includes gold.

14. The semiconductor package of claim 11, wherein the first conductive pad further includes a first seed pattern and a second seed pattern stacked downwardly in the vertical direction, wherein the first conductive pattern is disposed beneath the second seed pattern, and
wherein the first seed pattern includes titanium, and the second seed pattern includes copper.

15. The semiconductor package of claim 14, wherein the second conductive pad further includes a third seed pattern and a fourth seed pattern stacked upwardly in the vertical direction, wherein the third conductive pattern is disposed on the fourth seed pattern, and
wherein the third seed pattern includes titanium, and the fourth seed pattern includes copper.

16. A semiconductor package comprising:
a buffer die;
first memory dies stacked on the buffer die;
a second memory die disposed on an uppermost first memory die of the first memory dies;
a bonding layer disposed between the first memory dies and between the uppermost first memory die and second memory die, wherein the bonding layer bonds the uppermost first memory die and second memory die with each other; and
a molding member disposed on the buffer die, wherein the molding member covers sidewalls of the first memory dies and the second memory die,
wherein:
each of the first memory dies includes:
a first substrate having first and second surfaces that are opposite to each other in a vertical direction substantially perpendicular to an upper surface of the buffer die;
a first through electrode structure extending through the first substrate, wherein a portion of the first through electrode structure protrudes beyond the second surface of the first substrate;
a first protective pattern structure disposed on the second surface of the first substrate, wherein the first protective pattern structure covers the portion of the first through electrode structure and includes:
a first protective pattern; and
a second protective pattern disposed on the first protective pattern;
a first conductive pad and a first conductive connection member that are stacked beneath the first surface of the first substrate in the vertical direction; and
a second conductive pad disposed on the first protective pattern structure, wherein the second conductive pad contacts the first through electrode structure,
the second conductive pad of a first first memory die of the first memory dies contacts the first conductive connection member of a second first memory die of the first memory dies, wherein the first first memory die is disposed under the second first memory die,
the first conductive pad includes a first conductive pattern and a second conductive pattern stacked downwardly in the vertical direction,
the second conductive pad includes a third conductive pattern and a fourth conductive pattern stacked upwardly in the vertical direction,
the fourth conductive pattern contacts the third conductive pattern, and
each of the first and third conductive patterns includes nickel, wherein the second conductive pattern includes copper, and the fourth conductive pattern includes gold.

17. The semiconductor package of claim 16, wherein the buffer die includes:
a second substrate having first and second surfaces that are opposite to each other in the vertical direction;
a second through electrode structure extending through the second substrate, wherein a portion of the second through electrode structure protrudes beyond the second surface of the second substrate; and
a second protective pattern structure disposed on the second surface of the second substrate, wherein the second protective pattern structure covers the portion of the second through electrode structure and includes:
a third protective pattern; and
a fourth protective pattern disposed on the third protective pattern.

18. The semiconductor package of claim 17, wherein the buffer die further includes:
a third conductive pad and a second conductive connection member that are stacked beneath the first surface of the second substrate in the vertical direction; and
a fourth conductive pad disposed on the second protective pattern structure, wherein the fourth conductive pad contacts an upper surface of the second through electrode structure, and
wherein the fourth conductive pad of the buffer die contacts the first conductive connection member of a lowermost first memory die of the first memory dies.

19. The semiconductor package of claim 18, wherein the first conductive pad further includes a first seed pattern and a second seed pattern stacked downwardly in the vertical direction, and the first conductive pattern is disposed beneath the second seed pattern, and
wherein the first seed pattern includes titanium, and the second seed pattern includes copper.

20. The semiconductor package of claim 19, wherein the second conductive pad further includes a third seed pattern and a fourth seed pattern stacked upwardly in the vertical direction, and the third conductive pattern is disposed on the fourth seed pattern, and
wherein the third seed pattern includes titanium, and the fourth seed pattern includes copper.
